(19) United States
(12) Patent Application Publication
(10) Pub. No.: US 2007/0070465 A1
(43) Pub. Date: Mar. 29, 2007

(54) Device color separation

(76) Inventors: Di-Yuan Tzeng, Eagle, ID (US); Steve A. Jacob, Boise, ID (US); Terry M. Nelson, Boise, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/232,788

(22) Filed: Sep. 22, 2005

(51) Int. Cl. G03F 3/08

(52) U.S. Cl. 358/518; 358/515

(57) ABSTRACT

Methods, computer readable media, and computing devices are provided for device color separation. One method embodiment includes defining target nodes on a target neutral axis of the hue profile by using a darkest target node and a lightest target node. The method includes defining target nodes on a target boundary of the hue profile by using a sampled hue profile formed by a color separation process. Target nodes inside the hue profile are defined by using target nodes on the target boundary.

### BACKGROUND

In the field of color printing, it is useful to perform device color separation on image data in a color exchange space to obtain device values that represent device colors in a physical color space. Device values that represent device colors can describe how much of each device color a particular output device should use in producing color images. Program instructions can execute so that a particular output device can use such device values to produce color images. It is useful to perform device color separation so that an output device can produce accurate and visually pleasing color images.

There are several methods to separate colors of image data. In one method, colors can be manually separated by a human operator, however manual color separation requires significant time by an experienced operator. In another method, program instructions can execute to perform Gray Component Replacement (GCR) to separate colors; however GCR can cause an output device to produce color images with undesirable effects, such as hue banding, saturation banding, saturation loss, and/or unbalanced neutrals (i.e. grays). In another method, program instructions can execute to perform Under Color Addition (UCA) to enhance color saturation in separated colors; however UCA can cause an output device to produce color images by using percentages of toner or ink outside of the device's output limit, causing undesirable mechanical wear on the device, which can shorten the device's life.

### BRIEF DESCRIPTION OF THE DRAWINGS

FIG. 1 illustrates an example of an output device suitable to produce a color image, according to an exemplary embodiment of the present disclosure.

FIG. 2 is a graph illustrating black generation curves, according to an exemplary embodiment of the present disclosure.

FIG. 3 is a flowchart illustrating a numerical printer model inversion, according to an exemplary embodiment of the present disclosure.

FIG. 4 is a chart illustrating data in a color exchange space for a neutral axis, according to embodiments of the present disclosure.

FIG. 5A illustrates a hue profile with an unbalanced neutral axis, an unevenly spaced boundary, and irregularly distributed inside nodes, according to an exemplary embodiment of the present disclosure.

FIG. 5B illustrates a hue profile with a balanced neutral axis, according to embodiments of the present disclosure.

FIG. 5C illustrates a partial hue profile, according to embodiments of the present disclosure.

FIG. 5D illustrates a partial hue profile with an evenly spaced boundary, according to embodiments of the present disclosure.

FIG. 5E illustrates a partial hue profile with a column of regularly distributed inside nodes, according to embodiments of the present disclosure.

FIG. 5F illustrates a hue profile with regularly distributed inside nodes, according to embodiments of the present disclosure.

FIG. 6A is a chart illustrating a method of processing a hue profile, according to embodiments of the present disclosure.

FIG. 6B is a chart illustrating a method of determining device values for a hue, according to embodiments of the present disclosure.

FIG. 6C is a chart illustrating a method for converting non-black device colors into process black device colors, according to embodiments of the present disclosure.

### DETAILED DESCRIPTION

Embodiments of the present disclosure include methods, computer readable media, and computing devices for device color separation. One method embodiment includes defining target nodes on a target neutral axis of the hue profile by using a darkest target node and a lightest target node. The method includes defining target nodes on a target boundary of the hue profile by using a sampled hue profile formed by a color separation process. Target nodes inside the hue profile are defined by using target nodes on the target boundary.

According to various embodiments of the present disclosure, program instructions can execute to perform a device color separation method that can quickly separate colors to obtain device values that can cause an output device to produce neutrally balanced colors within a largest color gamut achievable using toner/ink inside the device's output limit, resulting in accurate and visually pleasing color images, without causing undesirable mechanical wear on the device.

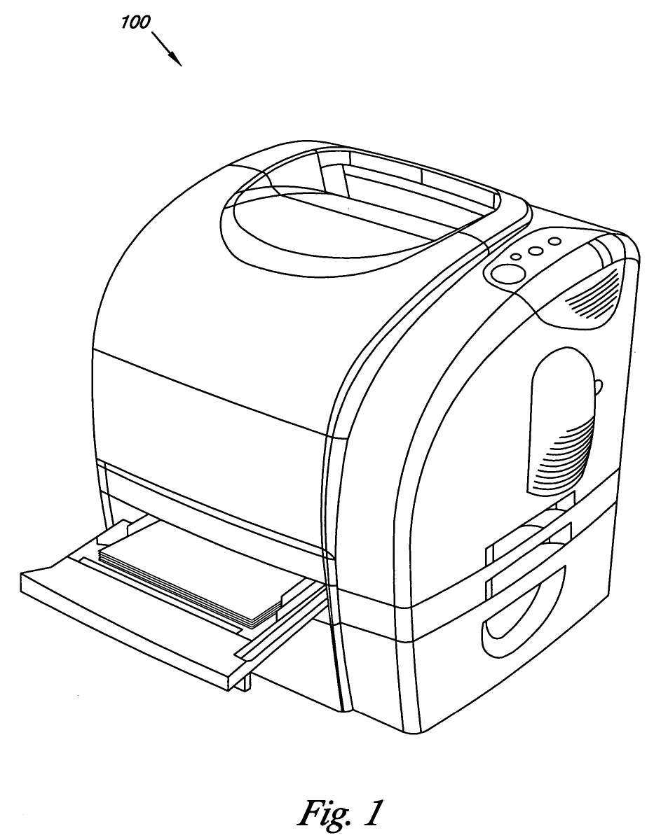

FIG. 1 illustrates an example of an output device suitable to produce a color image, according to an exemplary embodiment of the present disclosure. FIG. 1 illustrates a printing device 100, which can use device values to print color images, including color characters, on media, such as paper or transparent film. The printing device 100 can use device values, obtained from image data on which device color separation has been performed. Other examples of output devices include color copiers, color multi-function-peripherals, and color multi-functional printers.

Printing devices can use various printing techniques. Printing devices can print on media by using techniques such as firing ink jets and/or by using toner and a laser. Different embodiments of printers, including ink jet and laser printers, can print color images, including color characters.

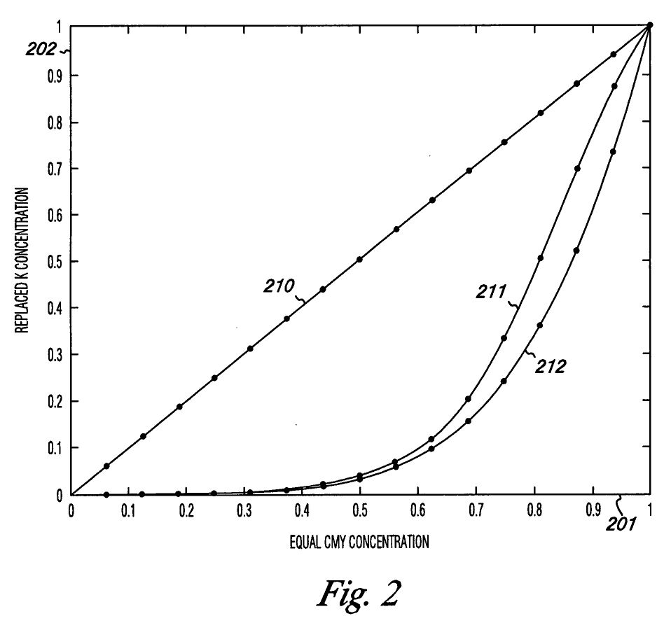

Printing devices can also use various device colors in printing. Printing devices can use device colors, such as cyan (C), magenta (M), yellow (Y), and black (K). Printing devices can use four, six, or another number of device colors in various combinations in printing. As one example, a printing device can print using non-black device colors, such as CMY, in which non-black device colors can combine to produce black in a printed color image. As another example, a printing device can print using process black device colors, such as CMYK, in which a device black color, K, can be used to produce black in a printed color image. In various printing embodiments, a black generation curve can be used to determine how much device black a printing device should use in process black device colors, as described in FIG. 2.

Color addition can enhance color saturation in separated device colors for an output device, such as those obtained from a gray component replacement method. UCA can enhance blackness. Color addition can enhance the color saturation by adding additional particular percentages of particular primary device colors of the output device. An output device has an output limit, that describes a largest percentage of toner or ink that the device should use to produce a color image, as will be understood by one of ordinary skill in the art. For example, an inkjet printing device that uses primary device colors CMYK can have an output limit of 220%, indicating that when the printing device produces a color image, a sum of a percentage of C, a percentage of M, a percentage of Y, and a percentage of K, should not exceed 220%. Program instructions can execute to perform a dominant color addition method, which determines additional percentages of particular colors that can be added to enhance color saturation of separated device colors for an output device to produce colors within a largest color gamut achievable using toner/ink inside the device's output limit.

A dominant color addition method can be performed on separated device colors for an output device. These separated device colors can be obtained from a color separation method, such as a GCR method. In this embodiment, the separated device colors are a first primary device color, a second primary device color, a third primary device color, and a black device color. In this embodiment, the color separation method provides a separation percentage for each separated device color, and at least a portion of the separated percentage of the black device color is a gray component replacement.

As an example, a GCR method can separate colors for an inkjet printing device into primary device colors C, M, Y, and K. This exemplary GCR method can reduce percentages of C, M, and Y by 10% and add 10% K as a replacement for the CMY reduction. For example, if C, M, and Y have initial percentages of 10%, 100%, and 100%, respectively, then this GCR reduces C from 10% to a separated percentage of 0%, reduces M from 100% to a separated percentage of 90%, and reduces Y from 100% to a separated percentage of 90%. In this example, if K has an initial percentage of 0%, then this GCR increases K from 0% to a separated percentage of 10%.

A dominant color addition method can be performed by using various equations. These equations can be used to determine additional percentages of device colors to be added, inside an output limit of the output device, as described herein. Program instructions can execute to perform a dominant color addition method, by using these equations. In various embodiments, the content of these equations can vary, depending on the separated percentages of the primary device colors, obtained from a color separation method. In each of these equations, the variables are defined as follows: A2 is the additional percentage of the second primary device color, OL is the output limit of the output device, S3 is the separated percentage of the third primary device color, S2 is the separated percentage of the second primary device color, and SK is the separated percentage of the black device color.

In one embodiment of dominant color addition, a color separation obtains a first separated primary device color with a separated percentage of zero, a second separated primary device color with a separated percentage equal to a first value, and a third separated primary device color with a separated percentage also equal to the first value, and an equation can be used to determine an additional percentage of the second primary device color and an additional percentage of the third primary device color, that can be added to enhance color saturation in separated colors. In one variation of this embodiment, the equation is A2≦1−S2. In another variation of this embodiment, the equation is A2≦(OL−S3−S2−SK)/2. Program instructions can execute to perform each of these equations.

In another embodiment of dominant color addition, a color separation obtains a first separated primary device color with a separated percentage of zero, a second separated primary device color with a separated percentage equal to a first value, and a third separated primary device color with a separated percentage also equal to a second value that is different than the first value, and an equation can be used to determine an additional percentage of the second primary device color and an additional percentage of the third primary device color, that can be added to enhance color saturation in separated colors. In one variation of this embodiment, the equation is A2=S2/S3*A3. In another variation of this embodiment, the equation is A2≦(OL−S3−S2−SK)/(1+S3/S2). In still another variation of this embodiment the equation is A2≦1−S2. Program instructions can execute to perform each of these equations.

FIG. 2 is a graph illustrating black generation curves, according to an exemplary embodiment of the present disclosure. A black generation curve can be used in device color separation to determine how much device black a particular output device should use in producing color images. FIG. 2 shows three black generation curves, each of which defines percentages of device color K to replace equal percentages of device colors C, M, and Y for a particular output device. The curves include a linear replacement black generation curve 210, a shifted sigmoid black generation curve 211, and a power function black generation curve 212. The graph of FIG. 2 shows these curves with reference to equal CMY concentration 201 and replaced K concentration 202, with 1 representing 100% on both axes.

A black generation curve can be used to produce color images with process black device values, instead of non-black device values. For example, a black generation curve can be used to produce color images with device values for CMYK, instead of device values for CMY. Using process black device values instead of non-black device values can enhance blackness in a color image, resulting in a more visually pleasing color image. Using process black device values instead of non-black device values can also reduce printing costs, since black toner/ink can be less expensive than non-black toner/ink

The black generation curves in FIG. 2 can be created in various ways. The linear replacement black generation curve 210 can be created by using a linear identity function. A linear black generation curve can also be created by performing a GCR. The shifted sigmoid black generation curve 211 can be created by using a sigmoid function, such as:

$$S ( x ) = \frac{max ( x ) - min ( x )}{1 + {ⅇ}^{- γ ( x - {x}_{0} )}}$$

where S(x) represents a resulting shifted sigmoid black generation curve, max(x) represents an upper end of a defined interval of real numbers, min(x) represents a lower end of the defined interval, e is a base of the natural logarithm, γ is a gamma of the sigmoid curve, x is within the defined interval, and x₀ is the center point of the defined interval.

The power function black generation curve 212 can be created in various ways, such as by using an exponential function. Program instructions can execute to use such functions to generate black generation curves. Black generation curves can also be created in various other ways, as will be understood by one of ordinary skill in the art.

Just as different black generation curves can be created in various ways, different black generation curves can be used to create various effects. A shifted sigmoid black generation curve and a power function black generation curve can be used to reduce the use of black in highlight areas of a color image. In some instances, this reduction can prevent graininess in an image. In other instances, this reduction can increase surface glossiness of an image. Black generation curves can also be used to create various other effects, as will be understood by one of ordinary skill in the art.

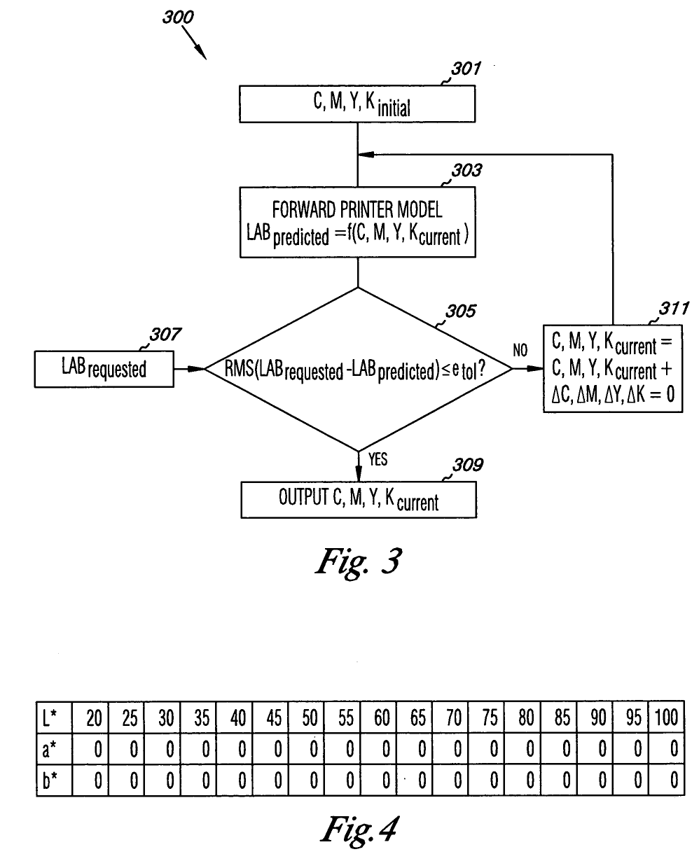

Since different black generation curves can create various effects, when using a black generation curve in a device color separation, it is desirable to select a curve that allows an output device to produce accurate and visually pleasing color images. For example, it is desirable to select a black generation curve that can cause an output device to use toner/ink inside the device's output limit to produce neutrally balanced colors. This use of toner/ink inside the device's output limit can reduce mechanical wear on the device, which can extend the device's life. A black generation curve can be selected, according to embodiments of the present disclosure, as described in FIG. 3.

FIG. 3 is a flowchart illustrating a numerical printer model inversion, according to an exemplary embodiment of the present disclosure. A numerical printer model inversion can be used in selecting a black generation curve for use in a device color separation. In one embodiment of the present disclosure, a black generation curve can be selected by choosing a potential curve and verifying an accuracy of the potential curve on a neutral axis for the device of the color separation. The accuracy of the potential curve can be verified by using a numerical printer model inversion. If the accuracy is verified as being less than an error tolerance, then the potential curve can be selected for use in a device color separation. If the accuracy is verified as being greater than the error tolerance, then another black generation curve can be selected. This selection and verification can be repeated until a black generation curve is selected with an accuracy that is verified as being less than the error tolerance. Program instructions can execute to verify the accuracy of a potential black generation curve, as described herein.

FIG. 3 shows a numerical printer model inversion technique 300. In FIG. 3, CMYK values and LAB values are used by way of example and not as limitations. As shown, CMYK represents device values for printing with four device colors, however, the technique 300 can be used with values for printing using other device colors in various combinations, as described herein. As shown, LAB represents color exchange space values in Commission International de l'Eclairage L*a*b* space (CIELAB), however, the technique 300 can be used for values in other color exchange spaces. Throughout this disclosure, a reference to CMYK values is intended to also serve as a reference to device values, and a reference to LAB values is also intended to serve as a reference to values in a color exchange space.

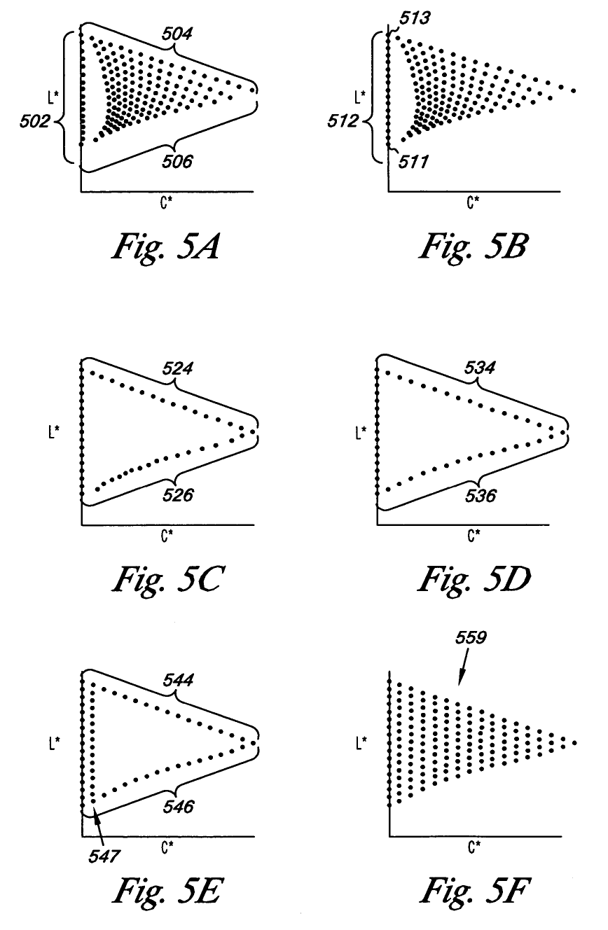

The technique 300 illustrates an iterative method for determining whether particular CMYK values can accurately represent target LAB values. Block 301 contains initial CMYK values; initial guesses for C, M, Y, and K, which are sent to Block 303. An initial guess for K can be determined by using a black generation curve, as described in FIG. 4. Block 303 contains a forward printer model, which uses received CMYK values to predict a LAB value. The forward printer model can be based on a polynomial regression model, a non-linear interpolation map, or other inverted printer models as will be understood by one of ordinary skill in the art. The predicted LAB value is sent to Block 305.

Block 305 contains a comparison function. Block 307 contains the target LAB, chosen based upon certain color characteristics, and is also sent to Block 305. The comparison function of Block 305 takes the root-mean-square (RMS) of the difference between the target LAB and the predicted LAB, and compares the result with an error tolerance. As shown in Block 305, the comparison function determines whether the result is less than or equal to an error tolerance, eₜₒₗ, such as, for example, 0.001. In variations of this embodiment, the error tolerance can be selected to be other values.

If the comparison function determines that the result is not less than the error tolerance, then the current CMYK value last used by the forward printer model to predict the predicted LAB value is sent to Block 311. Block 311 contains an increment function, which increments the current guess for C, M, Y, and K to form a new guess for C, M, Y, and K, which is sent to Block 303. The technique 300 can iterate through a loop from Block 311 to Block 303 to Block 305 and, if the next result is also not less than the error tolerance, again back to Block 311. In one embodiment of the present disclosure, C, M, and Y can be incremented while the new guess can include the same K used in the initial guess, as described above. The technique 300 can iterate through this loop until a result is less than the error tolerance or until an outside control terminates the iterations. If the comparison function determines that the result is less than the error tolerance, then the current CMYK value is sent to Block 309 as the output CMYK, which accurately represents the target LAB values of Block 307 within the error tolerance of Block 305.

Program instructions can execute to perform this numerical printer model inversion technique 300. The technique 300 can be used to select a black generation curve for use in a device color separation, as described in FIG. 4.

FIG. 4 is a chart illustrating data in a color exchange space for a neutral axis, according to embodiments of the present disclosure. The data in the chart of FIG. 4 can represent a neutral axis for different hues and is not limited to a particular hue. This chart can be used, along with the numerical printer model inversion technique 300 of FIG. 3, to select a black generation curve for use in a device color separation. The chart of FIG. 4 and the technique of FIG. 3 can verify an accuracy of a potential black generation curve at points on a neutral axis of an output device.

The chart of FIG. 4 illustrates equally spaced points along the neutral axis of the hue. At the left end of the chart, at L*=20 is a black point for the output device. At the right end of the chart, at L*=100 is a white point for the output device. In the middle of the chart, are points that are equally spaced in terms of lightness. The chart of FIG. 4 represents a target neutral axis of the hue. Program instructions can execute to define a black point and a white point for an output device, and to define equally spaced middle points between the black point and the white point. The chart of FIG. 4 can be used to determine the accuracy of a potential black generation curve, by providing LAB values for points along a target neutral axis, which can be compared to LAB values from the numerical printer model inversion technique 300 of FIG. 3.

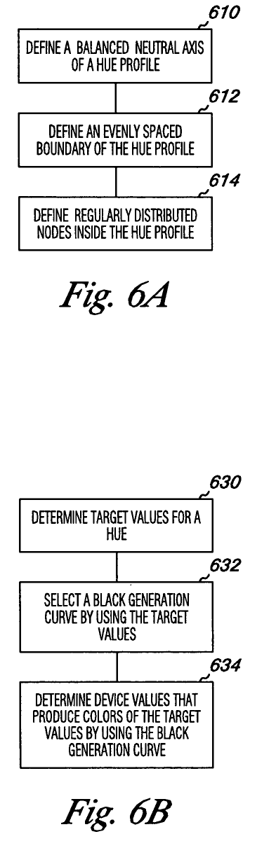

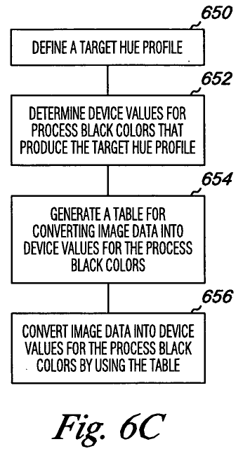

FIGS. 5 and 6 illustrate embodiments of a method of the present disclosure. Unless explicitly stated, the method embodiments described herein are not constrained to a particular order or sequence. Additionally, some of the described method embodiments or elements thereof can occur or be performed at the same point in time.

The embodiments described herein can be performed by software and/or firmware (i.e., computer executable instructions), hardware, application modules, and the like, executable and/or resident on the systems and devices shown herein or otherwise. The embodiments of the invention are not limited to any particular operating environment or to instructions written in a particular programming language. Software, firmware, and/or processing modules, suitable for carrying out embodiments of the present invention, can be resident in one or more devices or locations. Processing modules can include separate modules connected together or include several modules on an application specific integrated circuit (ASIC).

FIGS. 5A-5F shows hue profiles (i.e. hue leaves) and portions of hue profiles plotted as chromaticity graphs, in terms of lightness and chroma, as will be understood by one of ordinary skill in the art. In FIGS. 5A-5F, lightness increases from bottom to top and chroma increases from left to right. In the embodiments of FIGS. 5A-5F, each dot represents a node, with a lightness (L*) and a chrominance (C*), that can be expressed as color exchange space values, for example, CIELAB. In FIGS. 5A-5F, the L* and C* values represent polar forms of CIELAB values, as will be understood by one of ordinary skill in the art.

FIG. 5A illustrates a hue profile with an unbalanced neutral axis, an unevenly spaced boundary, and irregularly distributed inside nodes, according to an exemplary embodiment of the present disclosure. The hue profile in FIG. 5A is a sampled hue profile that is formed by a color separation process, as will be understood by one of ordinary skill in the art. In one embodiment, the color separation process can include GCR. In another embodiment, the color separation process can include color addition methods, such as the dominant color addition methods described herein. A color separation process can form a hue profile for a primary color, such as red, green, blue, cyan, magenta, or yellow. In alternate embodiments, a sampled hue profile can be obtained by other color processing techniques. Program instructions can execute to perform a color separation process, to form a sampled hue profile as described in FIG. 5A.

The sampled hue profile of FIG. 5A includes an unbalanced neutral axis 502, an unevenly spaced boundary with a top portion 504 and a bottom portion 506, and irregularly distributed inside nodes. In FIG. 5A, each dot represents a sampled node. The unbalanced character of the neutral axis 502 is shown by dots on the left side of the hue profile. In the embodiment of FIG. 5A, the dots of the neutral axis 502 are illustrated as a crooked line, indicating that, for the sampled hue, the neutral coloring is unbalanced for the neutral axis 502. The irregularly distributed inside nodes are shown by dots inside the neutral axis 502 and the boundary formed by the top portion 504 and the bottom portion 506. In the embodiment of FIG. 5A, the dots of the inside nodes are illustrated as not regularly distributed, indicating that, for the sampled hue, the hue coloring is neither smooth nor uniform in gradient.

FIG. 5B illustrates a hue profile with a balanced neutral axis, according to embodiments of the present disclosure. FIG. 5B also illustrates a hue profile with an unevenly spaced boundary and irregularly distributed inside nodes, similar to those shown in FIG. 5A. In FIG. 5B, a neutral axis 512 is shown by dots on the left side of the hue profile. Each dot on the left side of the hue profile of FIG. 5B represents a target node on the neutral axis 512. In the embodiment of FIG. 5B, the dots of the neutral axis are illustrated as a straight vertical line, indicating that the neutral coloring for the neutral axis 512 of the hue profile is balanced. This balanced neutral axis 512 is formed by defining the target nodes on the neutral axis 512. According to various embodiments, program instructions execute to define target nodes can be defined in terms of their color exchange space values. That is, program instructions can execute to define target nodes on a neutral axis of a hue profile, including defining target nodes in terms of their color exchange space values.

In FIG. 5B, the program instructions execute to define the target nodes on the neutral axis of the hue profile using a darkest node 511. The darkest node 511 represents a darkest black color that an output device can produce (i.e. black point). For example, for a particular media an output device can have a darkest node wherein, in CIELAB, L*=20, a*=0, and b*=0. However, various output devices can have different L* values for their darkest nodes. In FIG. 5B, the darkest node 511 forms a bottom point on the neutral axis 512, similar to the darkest value in the chart of FIG. 4.

Program instructions can also execute to define the balanced neutral axis 512 using a lightest node 513. In the embodiment of FIG. 5B, the lightest target node 513 represents a lightest white color that an output device can produce (i.e. white point). For example, an output device has a lightest target node wherein, in CIELAB, L*=100, a*=0, and b*=0. In FIG. 5B, the lightest target node 513 forms a top point on the neutral axis 512, similar to the lightest value in the chart of FIG. 4.

Program instructions execute to define inside neutral axis nodes on the balanced neutral axis 512 using the darkest target node 511 and the lightest target node 513. In the embodiment of FIG. 5B, the inside neutral axis nodes represent neutral colors with lightness values between the darkest target node 511 and the lightest target node 513. According to embodiments of the present disclosure, for inside neutral axis nodes a*=0 and b*=0. In FIG. 5B, the inside neutral axis nodes form a middle on the neutral axis 512, similar to the middle values in the chart of FIG. 4.

In FIG. 5B, the target nodes on the neutral axis 512 form a straight line because a*=0 and b*=0 for those nodes. As illustrated in the embodiment of FIG. 5B, the target nodes on the neutral axis 512 are equally spaced on the lightness scale, similar to the values in the chart of FIG. 4. Program instructions execute to define this equal spacing for the inside neutral axis nodes with equally spaced lightness values. For example, for seventeen target nodes on a neutral axis, spaced from L*=20 to L*=100, each inside neutral axis node can be spaced apart by increments of 5 units on a lightness scale, as shown in FIG. 4. In FIG. 5B, the target nodes on the balanced neutral axis 512 include the darkest node 511, the lightest node 513, and the inside neutral axis nodes, i.e. nodes between the darkest node 511 and the lightest node 513, for a*=0 and b*=0. A balanced neutral axis can also be considered a target neutral axis.

In one embodiment of the present disclosure, there can be a number of target nodes on a neutral axis equal to a dimension of a look-up-table for converting non-black device colors to process black device colors. For example, a 17×17×17 look-up table for converting CMY to CMYK, has a dimension of 17, and there can be 17 target nodes on a neutral axis, e.g. the neutral axis 512 of FIG. 5B. Program instructions can execute to define a target neutral axis, as described in FIG. 5B.

FIG. 5C illustrates a partial hue profile, according to embodiments of the present disclosure. FIG. 5C also illustrates a partial hue profile with a balanced neutral axis and an unevenly spaced boundary, similar to those shown in FIG. 5B. In FIG. 5C, sampled inside nodes of the hue profile are removed, to illustrate characteristics of an unevenly spaced boundary. The unevenly spaced boundary is shown by dots that form a top portion 524 and a bottom portion 526 of the boundary of the hue profile, wherein each dot on the boundary represents a sampled node of a sampled hue profile. In the embodiment of FIG. 5C, the dots of the boundary are illustrated as unequally spaced on the chroma scale, indicating that the hue coloring for the boundary of the hue profile is not uniform in chroma, C*.

FIG. 5D illustrates a partial hue profile with an evenly spaced boundary, according to embodiments of the present disclosure. FIG. 5D also illustrates a partial hue profile with a balanced neutral axis, similar to that shown in FIG. 5C. In FIG. 5D, a boundary is shown by dots that form a top portion 534 and a bottom portion 536 of the boundary of the hue profile, wherein each dot represents a target node on the boundary. In the embodiment of FIG. 5D, the dots of the boundary are illustrated as equally spaced on the chroma scale, indicating that the hue coloring for the boundary of the hue profile is uniform in chroma, C*. Program instructions execute to form this boundary by defining the target nodes on the boundary. As with the neutral axis, program instructions execute to define the target nodes on the boundary in terms of their color exchange space values.

In FIG. 5D, program instructions execute to define the target nodes on the boundary of the hue profile using a sampled boundary of a sampled hue profile, such as the sampled hue profile of FIG. 5A. As described in Figure 5A, the unevenly spaced boundary of the sampled hue profile has the top portion 504 and the bottom portion 506. This sampled boundary can be described by one or more functions, which define lightness as a function of chroma. For example, the sample boundary can be described by linear regression, direct linear interpolation, or non-linear interpolation. Alternatively, other mathematical models can be used to describe the sample boundary, as will be understood by one of ordinary skill in the art. In one embodiment of the present disclosure, a first function can define the top portion 534 and a second function can define the bottom portion 536. Program instructions can execute to define target nodes on a boundary of a hue profile, including using one or more functions which describe a sampled boundary of a sampled hue profile.

In the embodiment of FIG. 5D program instructions execute using a function, which describes the sampled boundary and defines lightness as a function of chroma, to define target nodes on the boundary at chroma values that are equally spaced apart on a chroma scale. In this embodiment, a particular chroma value can be processed through the function(s) to yield a target node with a particular lightness value for the top portion of the boundary and a target node with a particular lightness value for the bottom portion of the boundary. In the embodiment of FIG. 5D, this forms an evenly spaced boundary, on which, target nodes are equally spaced apart on the chroma scale, indicating that the hue coloring for the boundary of the hue profile is uniform in chroma, C*. In various embodiments of this invention, this method can produce an evenly spaced boundary formed with straight lines, curved lines, or other shapes depending on the function(s) used. An evenly spaced boundary can also be considered a target boundary. Hence, program instructions execute to define a target boundary, as described in FIG. 5D, including a target boundary with target nodes at evenly spaced chroma values.

FIG. 5E illustrates a partial hue profile with a column of regularly distributed inside nodes, according to embodiments of the present disclosure. FIG. 5E also illustrates a partial hue profile with a balanced neutral axis and an evenly spaced boundary, similar to those shown in FIG. 5D. In FIG. 5E, a single column of regularly distributed nodes 547 is shown to illustrate a method that can be applied to form individual columns. In one embodiment, program instructions execute to form the column 547 by interpolating between a target node on a top portion 544 of a boundary of the hue profile and a bottom portion 546 of a boundary of the hue profile. This interpolation can be linear or nonlinear. In another embodiment, program instructions execute to form the column 547 by equally spacing apart a number of inside on a lightness scale. In the embodiment of FIG. 5E, inside dots in the column 547 represent inside nodes. The regular distribution of dots, illustrated in this embodiment, indicates that, for the portion of the hue represented by the column 547, the hue coloring is smooth and uniform in gradient. Regularly distributed inside nodes can also be considered target nodes inside a hue profile. Thus, according to various embodiments, program instructions can execute to define target nodes inside a hue profile, as described in FIG. 5E, including defining such target nodes in a column.

FIG. 5F illustrates a hue profile with regularly distributed inside nodes, according to embodiments of the present disclosure. FIG. 5F also illustrates a hue profile with a balanced neutral axis and an evenly spaced boundary, similar to those shown in FIG. 5E. FIG. 5F illustrates the results of repeating program instruction execution to perform the method of creating a column of regularly distributed inside nodes 559, as described in FIG. 5E. That is, the program instructions repeatedly execute to create similar columns at other chroma values. As a result, the entire hue profile includes regularly distributed inside nodes 559.

Accordingly, in one embodiment of the present disclosure, program instructions can execute to perform a device color separation method, to define a hue profile, in which: a neutral axis transitions from a top point with a lightest neutral and no hue to a bottom point with a darkest neutral and no hue; a bottom portion of a boundary of the hue profile transitions from the bottom point on the neutral axis to a cusp with no neutral and pure hue; and a top portion of a boundary of the hue profile transitions from the cusp back to the top point on the neutral axis.

In FIG. 5, the distribution appears regular in terms of both lightness and chroma, however, in various embodiments a regular distribution on a lightness scale can be independent of a regular distribution on a chroma scale. For example, inside nodes may have a first regular distribution on a lightness scale, and a second regular distribution on a chroma scale. Hence, program instructions can execute to define target nodes inside a hue profile, as described in FIG. 5F, including defining such target nodes column by column.

In one embodiment, program instructions can execute to define target nodes inside multiple hue profiles so that target nodes can be defined for an entire color space. For example, target nodes can be defined for an entire color space by defining target nodes for hue profiles of primary device colors and interpolating between the target nodes of the hue profiles.

FIG. 6A is a chart illustrating a method of processing a hue profile, according to embodiments of the present disclosure. In Block 610, a balanced neutral axis of a hue profile is defined, as described in FIG. 5B, defining target nodes on a neutral axis, wherein at each target node, in CIELAB, a*=0, and b*=0. An evenly spaced boundary of the hue profile is defined, in Block 612, as described in FIG. 5D, defining lightness values for target nodes on top and bottom portions of the boundary at equally spaced chroma values. In Block 614, regularly distributed inside nodes of the hue profile are defined, as described in FIGS. 5E and 5F, resulting in regular distributions on a lightness scale and on a chroma scale. Performing the methods of Blocks 610, 612, and 614 can result in a hue profile with balanced neutral coloring, and smooth hue coloring that is uniform in gradient. Program instructions can execute to perform the methods of Blocks 610, 612, and 614, as described in FIG. 6A.

FIG. 6B is a chart illustrating a method of determining device values for a hue, according to embodiments of the present disclosure. In Block 630, target values for a hue are determined, as described in FIG. 5. These target values can be color exchange space values. A black generation curve is selected in Block 632, by using the target values from Block 630, as described in FIG. 3. In Block 634, device values for an output device are determined by using the black generation curve selected in Block 632. These are device values for process black device colors of the output device that produce the target values of block 630. Performing the methods of Blocks 630, 632, and 634 can result in device values for device colors such as CMYK that can be used by the output device to produce the hue. Program instructions can execute to perform the methods of Blocks 630, 632, and 634, as described in FIG. 6B.

FIG. 6C is a chart illustrating a method for converting non-black device colors into process black device colors, according to embodiments of the present disclosure. In Block 650, a target hue profile is defined, as described in FIG. 5. Device values that produce the target hue profile are determined in Block 652, as described herein. As in FIG. 6B, these device values are process black device colors. Once the connection between a target profile and device values is made, a look-up-table can be generated. In Block 654, a table is generated, for converting image data into device values for process black colors, by using data from Blocks 650 and 652. This table can be used to convert image data, as shown in Block 656. Program instructions can execute to perform the methods of Blocks 650, 652, 654, and 656, as described in FIG. 6C.

Although specific embodiments have been illustrated and described herein, those of ordinary skill in the art will appreciate that an arrangement calculated to achieve the same techniques can be substituted for the specific embodiments shown. This disclosure is intended to cover all adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the embodiments of the present disclosure require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed:

1. A method for determining color addition percentages comprising:
providing separated device colors for an output device, obtained from a color separation method, wherein the separated device colors include a separated percentage of a first primary device color, a separated percentage of a second primary device color, a separated percentage of a third primary device color, and a separated percentage of a black device color, wherein at least a portion of the separated percentage of the black device color is a gray component replacement; and
determining an additional percentage of second primary device color and an additional percentage of third primary device color that can be added to enhance color saturation of the separated device colors inside an output limit of the output device, by using an equation.

2. The method of claim 1 wherein:
the separated percentage of the first primary device color is zero;
the separated percentage of the second primary device color equals the separated percentage of the third primary device color;
the equation is A2≦1−S2, wherein:
A2 is the additional percentage of the second primary device color; and
S2 is the separated percentage of the second primary device color; and
the additional percentage of the second primary device color equals the additional percentage of the third primary device color.

3. The method of claim 1 wherein:
the separated percentage of the first primary device color is zero;
the separated percentage of the second primary device color equals the separated percentage of the third primary device color;
the equation is A2≦(OL−S3−S2−SK)/2, wherein:
A2 is the additional percentage of the second primary device color;
OL is the output limit of the output device;
S3 is the separated percentage of the third primary device color;
S2 is the separated percentage of the second primary device color; and
SK is the separated percentage of the black device color; and
the additional percentage of the second primary device color equals the additional percentage of the third primary device color.

4. The method of claim 1 wherein:
the separated percentage of the first primary device color is zero;
the separated percentage of the second primary device color does not equal the separated percentage of the third primary device color; and
the equation is A2=S2/S3*A3, wherein:
A2 is the additional percentage of the second primary device color;
S2 is the separated percentage of the second primary device color;
S3 is the separated percentage of the third primary device color; and
A3 is the additional percentage of the third primary device color.

5. The method of claim 1 wherein:
the separated percentage of the first primary device color is zero;
the separated percentage of the second primary device color does not equal the separated percentage of the third primary device color; and
the equation is A2≦(OL−S3−S2−SK)/(1+S3/S2), wherein:
A2 is the additional percentage of the second primary device color;
OL is the output limit of the output device;
S3 is the separated percentage of the third primary device color;
S2 is the separated percentage of the second primary device color; and
SK is the separated percentage of the black device color.

6. The method of claim 1 wherein:
the separated percentage of the first primary device color is zero;
the separated percentage of the second primary device color does not equal the separated percentage of the third primary device color; and
the equation is A2≦1−S2, wherein:
A2 is the additional percentage of the second primary device color; and
S2 is the separated percentage of the second primary device color.

7. A method of processing a hue profile comprising:
defining target nodes on a target neutral axis of the hue profile, by using a darkest target node and a lightest target node;
defining target nodes on a target boundary of the hue profile, by using a sampled hue profile formed by a color separation process; and
defining target nodes inside the hue profile, by using target nodes on the target boundary.

8. The method of claim 7, wherein:
the target nodes on the target neutral axis include:
the darkest target node;
the lightest target node, wherein, in CIELAB, L*=100; and
an inside neutral axis node; and
at each of the target nodes on the target neutral axis, in CIELAB, a*=0 and b*=0.

9. The method of claim 8, wherein the target nodes on the target neutral axis are equally spaced apart on a lightness scale.

10. The method of claim 9, wherein there are a number of target nodes on the target neutral axis equal to a dimension of a look-up-table for converting non-black device colors to process black device colors.

11. The method of claim 7 wherein defining the target nodes on the target boundary includes using a function that describes a sampled boundary of the sampled hue profile by defining lightness as a function of chroma.

12. The method of claim 11 wherein defining the target nodes on the target boundary includes defining target nodes on the target boundary at chroma values that are equally spaced apart on a chroma scale, by using the function.

13. The method of claim 7 wherein defining the target nodes inside the hue profile includes interpolating between:
a target node on a top portion of the target boundary; and
a target node on a bottom portion of the target boundary.

14. The method of claim 7 wherein target nodes inside the hue profile, at a particular chroma value, are equally spaced apart on a lightness scale.

15. A computer readable medium, having executable instructions thereon for causing a device to perform a method, comprising:
determining target color exchange space values for sampled nodes of a hue;
selecting a black generation curve, by using the target color exchange space values; and
determining target device values for device colors of an output device, that produce the target color exchange space values, by using the black generation curve.

16. The medium of claim 15, wherein selecting the black generation curve includes verifying the accuracy of the black generation curve for a neutral axis of the hue.

17. The medium of claim 16, wherein verifying the accuracy of the black generation curve includes:
determining predicted device values for device colors of the output device that produce the target color exchange space values for the sampled nodes on the neutral axis, by using a printer model inversion;
determining predicted color exchange space values that produce the predicted device values, by using a forward printer model; and
comparing the predicted color exchange space values with the target color exchange space values.

18. The medium of claim 15, wherein determining the target device values includes determining black device values, for a device black color that forms a portion of process black device colors of the output device, that produce the target color exchange space values, by using the black generation curve.

19. The medium of claim 18, wherein the method is repeated to determine target device values for an entire color space.

20. The medium of claim 18, wherein determining the target device values includes determining non-black device values, for non-black device colors that form a portion of the process black device colors of the output device, that produce the target color exchange space values, by using the black device values.

21. The medium of claim 18, wherein determining the target device values includes determining non-black device values, for non-black device colors that form a portion of the process black device colors of the output device, that produce the target color exchange space values, by using a printer model inversion.

22. The medium of claim 15, wherein the primary colors include red, green, blue, cyan, magenta, and yellow.

23. A computing device, comprising:
a processor;
a memory coupled to the processor;
program instructions storable in the memory and executable by the processor to:
define target nodes of a hue profile, wherein the target nodes form columns of nodes that are equally spaced apart on a chroma scale, and target nodes in each column are equally spaced apart on a lightness scale; and
determine device values for process black device colors of an output device, that produce colors represented by the target nodes, by using a black generation curve that describes the target nodes on a neutral axis of the hue profile.

24. The device of claim 23, including program instructions storable in the memory and executable by the processor to generate a table for converting image data into device values for the process black device colors of the output device.

25. The device of claim 24, including program instructions storable in the memory and executable by the processor to convert image data into device values, by using the table.

26. A device, comprising:
a processor;
a memory coupled to the processor; and
means for processing a sampled hue profile of a separated color to obtain a target hue profile in which target nodes form a neutral axis of the target hue profile so that the target hue profile has balanced neutral coloring.

27. The device of claim 26, including means for processing the sampled hue profile of the separated color to obtain the target hue profile in which target nodes form a target boundary of the hue profile so that the target hue profile uses a largest color gamut achievable on an output device inside an output limit of the output device.

28. The device of claim 27, including means for processing the sampled hue profile of the separated color to obtain the target hue profile in which target nodes inside the hue profile are regularly spaced so that the target hue profile has smooth hue coloring.
